(19) United States
(12) Patent Application Publication
(10) Pub. No.: US 2005/0156271 A1
(43) Pub. Date: Jul. 21, 2005

(54) Data storage device

(76) Inventors: Si-Ty Lam, Pleasanton, CA (US); Steve Naberhuis, Fremont, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/758,228

(22) Filed: Jan. 16, 2004

(51) Int. Cl. H01L 29/00

(52) U.S. Cl. 257/500

(57) ABSTRACT

The present invention pertains to a data storage device. The data storage device includes a storage medium having an electrode and an electrolyte layer positioned on the electrode. The data storage device also includes at least one probe configured to contact the electrolyte layer. In addition, the storage medium includes a voltage supply device configured to supply voltage through the at least one probe and the electrode to thereby create a circuit between the at least one probe and the electrode. The level of voltage supplied through the at least one probe allows at least one of writing, reading, and erasing operations on the one or more memory cells of the storage medium.

### BACKGROUND OF THE INVENTION

Memory devices are typically used in various electronic devices, for instance, computers and personal digital assistants. These memory devices may be characterized into various groups. Volatile memory devices comprise one of these groups. In volatile memory devices, the stored data or information is lost once the power source is disconnected. Examples of volatile memory devices are random access memory (“RAM”), dynamic RAM, and static RAM. In each of these types of memory devices, information is only retained so long as power is supplied to the devices.

Non-volatile memory devices comprise another group of memory devices. In non-volatile memory devices, data or information is retained in the memory device even when power is shut off. Examples of non-volatile memory devices include CD-ROMs and magnetic storage devices. Non-volatile memory devices may be preferable over volatile memory devices due in part to their ability to retain stored data or information in the absence of power; however, known non-volatile memory devices suffer from certain drawbacks. For instance, the devices cited above are typically relatively large, are shock/vibration-sensitive, require relatively expensive mechanisms, and consume relatively large amounts of power. These negative aspects typically make these memory devices non-ideal for low-power portable applications such as cell phones, palm-top computers and personal digital assistants (“PDAs”).

Another type of non-volatile memory device is based on a semiconductor technology known as FLASH. Although FLASH based memory devices are typically relatively small, they are somewhat limited in capacity because semiconductor lithographic processes are used to define the memory cells contained in these devices. Additional types of non-volatile memory devices are based on nano-probes. These memories are somewhat difficult to fabricate and have limitations in data rates and signal to noise (S/N) ratios.

Another type of non-volatile memory device known in the prior art is a programmable metallization cell (“PMC”). PMCs typically use chalcogenide glasses in non-volatile memory cells. Chalcogenide glasses employed in these types of memory cells typically comprise selenium (Se), sulfur (S), tellurium (Te), or combinations thereof. The PMC 10 depicted in FIG. 5 includes a supporting substrate 11 provided on a base of a fast ion conductor 12. A pair of opposing electrodes 13 and 14 are disposed on the surface of the fast ion conductor 12. The conductivity of the PMC 10 may be changed between highly resistive and highly conductive states. In its normal high resistive state, to perform a write operation,.an electrical potential is applied to a certain one of the electrodes 13 or 14, with the other of the electrode 13 or 14 being held at zero voltage or ground. The electrode 13 or 14 having the voltage applied thereto functions as an anode, while the electrode 13 or 14 held at zero or ground functions as a cathode. The nature of the fast ion conductor material 12 is such that it undergoes one or both of a chemical and structural change at a certain applied voltage. Specifically, at some suitable threshold voltage, plating of metal from metal ions within the fast ion conductor material 12 begins to occur on the cathode and grows or progresses through the fast ion conductor 12 toward the anode. With such voltage continued to be applied, the process proceeds until one or more conductive paths such as metallic dendrites or filaments 15 extend between the electrodes 13 and 14, effectively interconnecting the top and bottom electrodes to substantially increase the conductivity between them.

Although the use of PMCs has been found to be viable in storing data, known PMCs 10 have certain drawbacks and disadvantages. For instance, because the electrodes 13 and 14 are integrally formed with the fast ion conductor 12, an entire array of PMC 10 memory cells must have interconnects to allow addressing of each memory cell. This proposition may be associated with high fabrication costs due to the use of lithographic processes to realize reasonable storage densities. Alternatively, the PMC 10 may be arranged in a cross-point configuration as shown in AXON Technologies Corporation publications, in which either a resistor, or preferably a diode or transistor, is likely to be incorporated in each memory cell to prevent cross-talk. Incorporation of these components typically adds to the costs and difficulties associated with fabricating PMC memories.

### SUMMARY OF THE INVENTION

According to an embodiment, the present invention pertains to a data storage device. The data storage device includes a storage medium having an electrode and an electrolyte layer positioned on the electrode. The data storage device also includes at least one probe configured to contact the electrolyte layer. In addition, the storage medium includes a voltage supply device configured to supply voltage through the at least one probe and the electrode to thereby create a circuit between the at least one probe and the electrode. The level of voltage supplied through the at least one probe allows at least one of writing, reading, and erasing operations on the one or more memory cells of the storage medium.

### BRIEF DESCRIPTION OF THE DRAWINGS

Features of the present invention will become apparent to those skilled in the art from the following description with reference to the figures, in which:

FIG. 1 shows a simplified perspective view of a storage device according to an embodiment of the invention;

FIG. 2 shows a simplified elevational view of the storage device depicted in FIG. 1;

FIG. 3 shows a simplified perspective view of a storage device according to another embodiment of the invention;

FIG. 4 illustrates a simplified elevational view of the storage device depicted in FIG. 3; and

FIG. 5 shows a plan view of a conventional programmable metallization cell.

### DETAILED DESCRIPTION OF THE INVENTION

For simplicity and illustrative purposes, the present invention is described by referring mainly to an exemplary embodiment thereof. In the following description, numerous specific details are set forth in order to provide a thorough understanding of the present invention. It will be apparent however, to one of ordinary skill in the art, that the present invention may be practiced without limitation to these specific details. In other instances, well-known methods and structures have not been described in detail so as not to unnecessarily obscure the present invention.

A high-density storage device is provided for use in various electronic devices, for instance, computers, cell phones, lap-tops, PDAs, etc. The storage device includes a conductive probe operable to write information bits onto a storage medium, and operable to read information from the storage medium. The conductive probe is also operable to erase information from the storage medium. The writing, reading, and erasing operations may be performed through the level and bias of the voltage applied through the conductive probe.

In one example of the high-density storage device, the storage medium includes an electrolyte layer and an electrode. The conductive probe may conduct electricity through various areas of the electrolyte layer by forming a circuit with the electrode. In this regard, the conductivity through the various areas of the electrolyte layer may be altered during writing and erasing operations. In addition, the various areas of the electrolyte layer may also be addressed by the conductive probe during reading operations.

In another example, the high-density storage device includes a conductive layer positioned on the electrolyte layer. The conductive layer may include discontinuous conductive elements and the electrode may comprise a substantially continuous layer common to the discontinuous conductive elements. Each of the conductive elements may denote distinct memory cell locations. A substrate may also be positioned to support the electrode.

The conductive probe and the storage medium may be movable with respect to each other. For example, the conductive probe may be movable with respect to the storage medium, with the storage medium being held in a substantially fixed position. As another example, the storage medium may be movable with respect to the conductive probe, with the conductive probe being held in a substantially fixed position. As a further example, both the conductive probe and the storage medium may be movable with respect to each other. In one regard, through relative movement between the storage medium and the conductive probe, the conductive probe may address conductive elements variously located on the storage medium.

One example of a high density storage device includes an array of conductive probes. The array of conductive probes may be used such that each probe addresses an area of the storage medium with each area of the storage medium provided with separate interconnects. In this respect, multiple circuits may be accomplished substantially simultaneously.

Through implementation of various embodiments of the invention, data may be stored in memory cells formed in a relatively high density pattern, e.g., greater than 10 Gb/cm². The memory cells may also store the data in a substantially non-volatile manner. In addition, the memory cells may be configured and employed in a relatively simple and inexpensive manner as compared with certain known storage devices since, for instance, the lithographic requirements are substantially reduced.

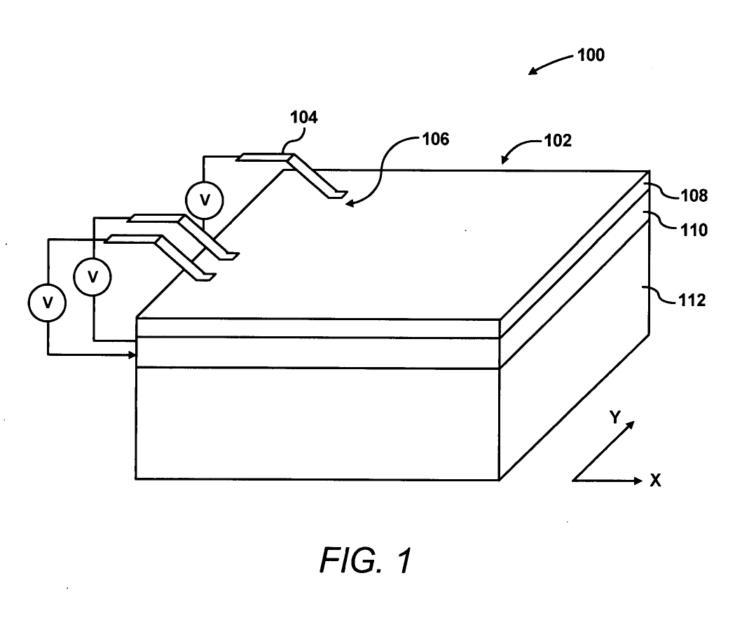

With reference first to FIG. 1, there is shown a simplified perspective view of a storage device 100 according to an embodiment of the invention. As depicted in FIG. 1, the storage device 100 includes a storage medium 102 and a conductive probe 104. The conductive probe 104 is configured to address various sections of the storage medium 102. The locations at which the conductive probe 104 addresses the storage medium 102 are considered memory cells 106. As described in greater detail hereinbelow, the memory cells 106 generally form locations on the storage medium 102 where information may be written, read, or erased. The memory cells 106 may comprise relatively small portions of the storage medium 102. In this regard, the storage medium 102 may be configured to include a relatively large number of memory cells 106 arranged, for instance, in a relatively dense array. In addition, the memory cells 106 may be provided at substantially any location along the storage medium 102 to thereby enable use of a relatively large number of memory cells 106.

As illustrated in FIG. 1, the conductive probe 104 is separate from the storage medium 102. At least by virtue of the separate configuration of the conductive probe 104 with respect to the storage medium 102, the conductive probe 104 and the storage medium 102 may be disengaged from each other in a relatively simple manner. For instance, the conductive probe 104 and the storage medium 102 may be separated from each other through disengagement of the voltage supply. In this regard, the storage medium 102 may be removed or replaced without requiring that the conductive probe 104 also be removed or replaced.

The storage medium 102 includes an electrolyte layer 108, having any reasonably suitable thickness to generally enable electrical flow therethrough, e.g., around 10-1000 nm thickness. According to an embodiment of the invention, the electrolyte layer 108 generally comprises a substantially solid structure composed of, for instance, chalcogenide glass, a metal-containing glass, a metal-containing amorphous semiconductor, a chalcogenide-metal material, etc. The electrolyte layer 108, in a broad sense, generally comprises any compound containing one or more of sulfur, selenium, and tellurium, whether ternary, quarternary or higher order compounds. More particularly, the electrolyte layer 108 may comprise materials selected from one or more of arsenic, germanium, selenium, tellurium, oxygen, sulfur, and antimony and the metals comprise materials from various metals, e.g., silver, gold, copper, iridium, platinum, palladium or combinations thereof. The chalcogenide-metal material may be fabricated through photodissolution, by depositing from a source comprising the chalcogenide and metal, or by any other reasonably suitable method known in the art. For instance, silver may be deposited into the electrolyte layer 108 in sufficient quantities to generally form an equilibrium phase throughout the electrolyte layer.

The electrolyte layer 108 is positioned on an electrode 110. As shown in FIG. 1, the electrode 110 is co-extensive along both the x and y directions with the electrolyte layer 108. In this regard, the electrode 110 may operate as a common electrode to the variously located memory cells 106. The electrode 110 may comprise any electrically conducting material, e.g., silver, gold, copper, palladium, platinum, combinations thereof, etc., capable of producing an electric field for the transport of metal ions in the electrolyte layer 108.

The electrode 110 is positioned on a substrate 112 configured to support the electrode 110. The substrate 112 may comprise any reasonably suitable material, e.g., silicon, silicon with oxide, glass, plastic, copper, etc.

As illustrated in FIG. 1, the storage device 100 includes a plurality of conductive probes 104. Although three conductive probes 104 are illustrated in FIG. 1, any number of conductive probes 104 may be included in the storage device 100 without departing from the scope of the invention. The selection of the number of conductive probes 104 to be employed with embodiments of the invention may be based, for instance, on the desired addressing speed or data transfer rate of the storage device 100. Thus, for example, if a faster addressing speed and higher data transfer rates are desired, the storage device 100 may be designed to include a larger number of conductive probes 104.

Either or both of the conductive probe(s) 104 and the storage medium 102 may be configured to move with respect to each other. Thus, for instance, the conductive probe(s) 104 may be positioned to address various areas on the electrolyte layer 110. In the event that the conductive probe(s) 104 are configured to move with respect to the storage medium 102, the conductive probe(s) 104 may be manipulated into various positions by, for instance, actuators (not shown) configured to move the conductive probe(s) 104. In addition, depending upon the arrangement of the conductive probe(s) 104, the actuators may be configured to manipulate the conductive probe(s) in either or both of the x and y directions. Thus, for instance, if an array of conductive probes 104 are positioned to address locations on the storage medium 102 along a y direction, the actuators may be configured to manipulate the conductive probes 104 in the x direction to generally enable addressing of a substantially large area of the storage medium by the conductive probes 104. As another example, the conductive probes 104 may be manipulated in both the x and y directions. The actuators may also be configured to manipulate the conductive probes 104 in a vertical direction with respect to the storage medium 102 to thereby disengage the conductive probes 104 from the electrolyte layer 108.

As another example, the storage medium 102 may be configured to move with respect to the conductive probe(s) 104. Movement of the storage medium 102 with respect to the conductive probe(s) 104 may be enabled through use of one or more actuators (not shown). Depending upon the configuration and number of conductive probes 104 employed in the storage device 100, the actuators may be configured to move the storage medium 102 in either or both of the x and y directions. In similar fashion to the disclosure hereinabove, the storage medium 102 may be moved to various positions with respect to the conductive probe(s) 104 to generally enable the conductive probe(s) 104 to address various locations on the storage medium 102.

According to an embodiment of the invention, the storage medium 102 may be positioned on a movable support as described in commonly assigned U.S. Pat. Nos. 6,181,050 and 6,411,589, the disclosures of which are hereby incorporated by reference in their entireties. In this regard, the movable support described in these patents may be employed to move the storage medium 102 with respect to the conductive probe(s) 104.

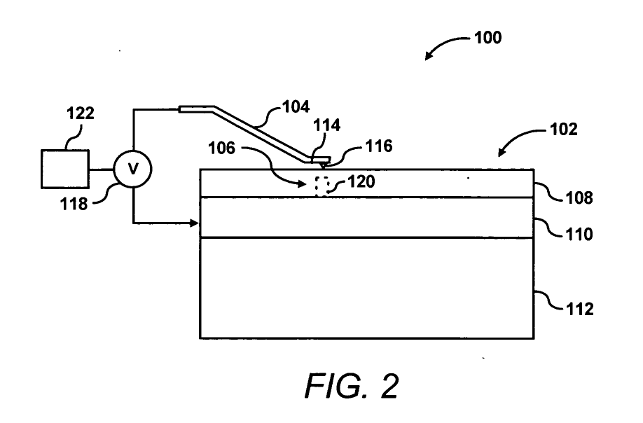

Turning now to FIG. 2, there is illustrated a simplified elevational view of the storage device 100 depicted in FIG. 1. The conductive probe 104 is depicted in greater detail in FIG. 2. As illustrated in FIG. 2, the conductive probe 104 contains an angled configuration. The conductive probe 104, may however, include any reasonably suitable configuration for addressing various locations on the electrolyte layer 108 without departing from the scope of the invention. For instance, the conductive probe 104 may comprise relatively perpendicular sections or a relatively straight configuration. In addition, the conductive probe 104 may comprise any reasonably suitable material capable of conducting electric current, e.g., silver, copper, platinum, palladium, gold, iridium, combinations thereof, heavily doped semiconductors such as Si, polysilicon, etc., metallized insulating or semiconducting materials where the metallization may comprise a suitable electrical conductor, etc.

The conductive probe 104 contains a contact section 114. The conductive probe 104 may include a tip 116 along the contact section 114 configured to address relatively small sections of the electrolyte layer 108, for instance, relatively densely arranged memory cells 106. The tip 116 generally comprises an inverted conical shape which may be micromachined with the conductive probe 104. The tip 116 may therefore be integrally formed with the conductive probe 104. Alternatively, however, the tip 116 may be separately attached to the contact section 114 of the conductive probe 104 without departing from the scope of the invention. The tip may comprise any reasonably suitable material capable of conducting electric charge, e.g., silver, copper, platinum, palladium, gold, iridium, combinations thereof, heavily doped semiconductors such as Si, polysilicon, etc., metallized insulating or semiconducting materials where the metallization may comprise a suitable electrical conductor, etc.

As described hereinabove, the conductive probe 104 is implemented to perform, write, read, and erase operations. To perform a write operation, the conductive probe 104 is positioned over a desired location on the electrolyte layer 108, for instance, a memory cell 106 location. The positioning of the conductive probe 104 over the desired location of the electrolyte layer 108 may be performed as described hereinabove. Once the conductive probe 104 is positioned over and is in contact with the desired location on the electrolyte layer 108, an electric potential is delivered by a voltage supply device 118 through the conductive probe 104, the electrolyte layer 108 and into the electrode 110, thereby creating a circuit. The voltage supply device 118 may comprise any reasonably suitable known device capable of supplying various levels of voltage through the conductive probe 104.

The voltage applied through the conductive probe 104 is sufficient to cause the metal in the electrode 110, which is an anode in this case, to become metal ions. The metal ions become dissolved in the electrolyte layer 108. The metal ions dissolved in the electrolyte layer 108 form or configure a conductive path such as a dendrite 120 by reduction and precipitation within the electrolyte. The growth of the dendrite 120 between the conductive probe 104 and the electrode 110 decreases the resistance in the electrolyte layer 108 in the memory cell 106 between the conductive probe 104 and the electrode 110.

The conductive probe 104 may be moved to another desired memory cell 106 location and the process described hereinabove may be repeated to write to the other desired memory cell 106. This process may be repeated any number of times to write data into any number of memory cells 106.

To perform a read operation, the conductive probe 104 is positioned over a desired memory cell 106. Again, the positioning of the conductive probe 104 over the desired memory cell 106 may be enabled in manners as described hereinabove. Once the conductive probe 104 is positioned over and in contact with the desired location on the storage medium 102, for instance, a desired memory cell 106, an electric potential is applied between the conductive probe 104 and the electrode 110. The level of voltage applied is selected to substantially prevent dendrite 120 formation in the electrolyte layer 108 in the memory cell 106. Thus, for instance, the voltage applied through the conductive probe 104 may be less than the voltage applied during a writing or erasing operation.

The level of resistance in the electrolyte layer 108 at the location of the memory cell 106 and the electrode 112 depends on the presence of a conductive path such as a dendrite 120. For instance, the resistance is lower between the conductive probe 104 and the electrode 110 when the dendrite 120 is present therebetween. Alternatively, the resistance between the conductive probe 104 and the electrode 110 is higher if there is no dendrite 120 formation in the memory cell 106.

The resistance in the electrolyte layer 108 at the location of the memory cell 106 may be detected by, for instance, a resistance measuring device 122. The resistance measuring device 122 may comprise any reasonably suitable conventional resistance measuring device capable of measuring the resistance in the electrolyte layer 108. The level of resistance may be characterized as 1's and 0's and the storage device 100 may comprise a binary memory storage system. Thus, for instance, each of the memory cells 106 may constitute a bit in the binary memory storage system.

In the memory cells 106, a higher resistance may, for instance, be characterized as a 0 and a lower resistance may be characterized as a 1, although the alternate characterization may also be employed without deviating from the scope of the invention. Thus, the conductive probe 104 may be implemented to determine whether the selected memory cell 106 is characterized as a 1 or a 0. In addition, through relative movement between the conductive probe 104 and the storage medium 102, the locations of the 1's and 0's may be determined through detection of the resistance at the various locations of the memory cells 106.

To perform an erase operation, the conductive probe 104 is positioned over a desired memory cell 106. The positioning of the conductive probe 104 over the desired memory cell 106 may be performed as described hereinabove. Once the conductive probe 104 is positioned over and is in contact with the desired memory cell 106, an electric potential is established between the conductive probe 104 and the electrode 110, thereby creating a circuit. The voltage applied through the conductive probe 104 has a reverse bias as compared with the potential applied during the writing operation described hereinabove. The reverse bias voltage generally causes the metal ions in the dendrite 120 to diffuse back to the electrode 110, to become metal again. In other words, the reverse bias voltage generally operates to reconfigure, or otherwise render less conductive, the dendrite 120 in the electrolyte layer 108. This operation causes the resistance in the electrolyte layer 108 at the location of the memory cell 106 to return to its high resistance state.

The erase operation may be repeated any number of times on variously “written” areas of the memory cells 106 to return those areas back to the high resistance state. In this regard, the conductive probe 104 may be maneuvered over the desired memory cells 106 to selectively perform the erase operations. In addition, the relative movement between the conductive probe 104 and the storage medium 102 may be implemented in any of the manners described hereinabove.

The storage device 100 may include additional components not specifically illustrated in FIGS. 1 and 2. For instance, the storage device 100 may include controllers designed to determine when and for which of the memory cells 106, read, write, or erase operations are to be performed. The storage device 100 may also include controllers for controlling the relative movements of the conductive probe 104 and the storage medium 102 as well as controllers for controlling the voltage to be applied through the conductive probe 104. The means of relative motion between the conductive probe 104 and the storage medium 102, for instance, a MEMS device, may also be included in the storage device 100.

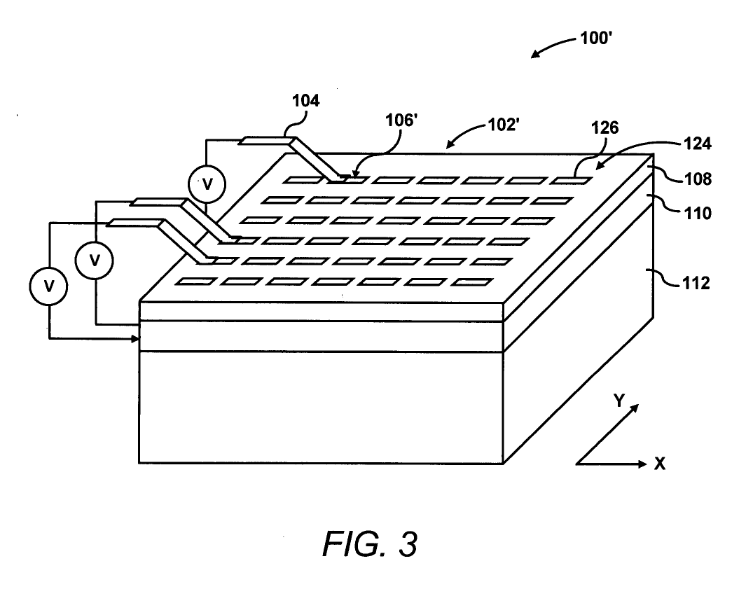

With reference now to FIG. 3, there is shown a simplified perspective view of a storage device 100′ according to another embodiment of the invention. The storage device 100′ includes all of the elements contained in the storage device 100. As such, only those elements contained in the storage device 100′ that differ from the elements contained in the storage device 100 are described hereinbelow. In addition, the storage device 100′ may include additional elements not specifically illustrated in FIG. 3 as described hereinabove with respect to the storage device 100 depicted in FIG. 1.

According to this embodiment, a storage medium 102′ of the storage device 100′ includes a conductive layer 124 composed of a plurality of conductive elements 126. The conductive elements 126 generally form physical locations for memorycells 106′. That is, for instance, each of the conductive elements 126 may form a memory cell 106′ location. The conductive elements 126 are arranged on the conductive layer 124 in a substantially discontinuous array. In other words, the conductive elements 126 are spaced apart from each other. The conductive elements 126 may be formed, for instance, by deposition of the desired conductive material and by conventional photolithography and etching processes. In addition or alternatively, the conductive elements 126 may be formed through conventional nano self-assembly techniques.

The conductive elements 126 may be spaced a sufficient distance apart from each other to substantially prevent conduction between the conductive elements 126, for instance, when a voltage is applied by a conductive probe 104. The spacing between the conductive elements 126 may be selected based upon a plurality of factors. These factors may include, for instance, the materials comprising the conductive elements, the physical limitations of processes employed to create and position the conductive elements 126, etc.

A relatively small number of conductive elements 126 are depicted in FIG. 3 for purposes of simplicity of illustration. It should, however, be understood that the storage medium 102′ may comprise any number of conductive elements 126 without departing from the scope of the invention. For instance, the number of conductive elements 126 contained in the storage medium 102 may be selected according to a desired storage capacity as each of the conductive elements 126 may represent a bit or a memory cell 106′ in the storage medium 102′.

The conductive elements 126 may comprise any reasonably suitable electrically conductive material. For instance, the conductive elements 108 may comprise platinum, platinum alloys (e.g., a platinum-iridium alloy), gold, iridium, silver, palladium, copper, or other such material that does not comprise or form an insulating oxide such as those of refractory metals (molybdenum, niobium, tantalum, zirconium, hafnium), etc. In addition, the conductive elements 126 may comprise a relatively thin film of material, e.g., around 5-500 nm thickness.

The conductive elements 126 are supported on the electrolyte layer 108, which is positioned on the electrode 110. As shown in FIG. 3, the electrode 110 is substantially co-extensive along both the x and y directions with the array of conductive elements 126 of the conductive layer 124. In this regard, the electrode 110 may operate as a common electrode to the conductive elements 126. The electrode 110 is also illustrated as being positioned on the substrate 112.

As illustrated in FIG. 3, the storage device 100′ includes a plurality of conductive probes 104. Although three conductive probes 104 are illustrated in FIG. 3, any number of conductive probes 104 may be included in the storage device 100′ without departing from the scope of the invention. For instance, the storage device 100′ may include a single conductive probe 104, the same number of conductive probes 104 as the conductive elements 126 along either the x or y direction, the same number of conductive probes 104 as the conductive elements 126, and any number of conductive probes 104 therebetween. The selection of the number of conductive probes 104 to be employed with embodiments of the invention may be based, for instance, on the desired addressing speed or data transfer rate of the storage device 100′. Thus, for example, if a faster addressing speed or higher data transfer rates are desired, the storage device 100′ may include a larger number of conductive probes 104.

The conductive probes 104 and the storage medium 102′ may be moved with respect to each other in any of the manners described hereinabove to enable the conductive probes 102 to address various ones of the conductive elements 126.

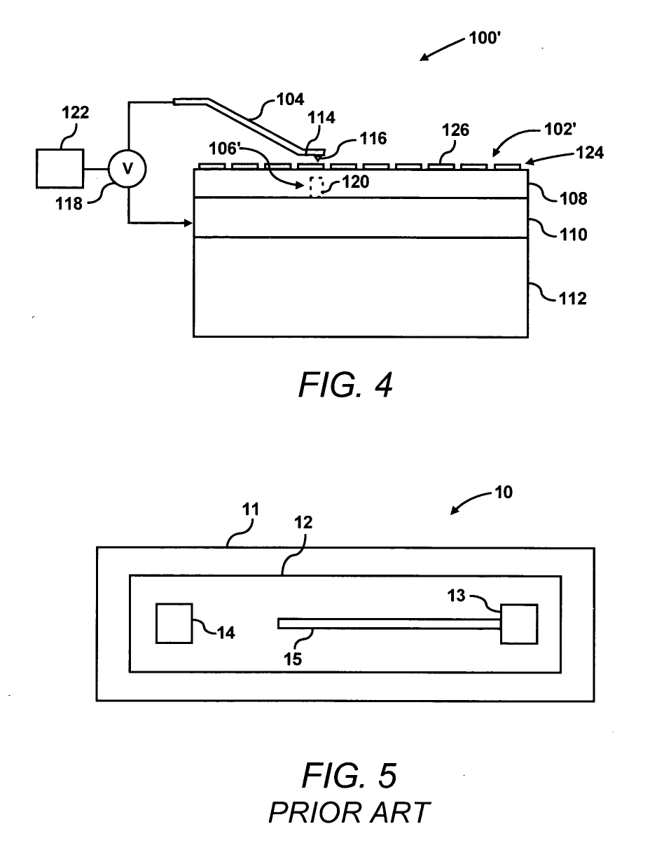

FIG. 4 illustrates a simplified elevational view of the storage device 100′ depicted in FIG. 3. The conductive probe 104 and conductive elements 126 are depicted in greater detail in FIG. 4. The storage device 100′ depicted in FIG. 4 includes all of the elements contained in the storage device 100 depicted in FIG. 2. As such, only those elements illustrated in FIG. 4 that differ from the elements illustrated in FIG. 2 are described hereinbelow.

The contact section 114 of the conductive probe 104 may be substantially equal in size to or smaller than the conductive elements 126. In this regard, the conductive probe 104 may be configured to address the conductive elements 126 individually. In addition, the conductive probe 104 may include a tip 116 along the contact section 114 configured to address the conductive elements 126 individually, for instance, when the contact section 114 is relatively larger than the conductive elements 126.

As described hereinabove, the conductive probe 104 is implemented to perform write, read, and erase operations. To perform a write operation, the conductive probe 104 is positioned over a desired conductive element 126. The positioning of the conductive probe 104 over the desired conductive element 126 may be performed as described hereinabove. Once the conductive probe 104 is positioned over and is in contact with the desired conductive element 126, an electric potential is established by the voltage supply device 118 through the conductive probe 104, the conductive element 126, the electrolyte layer 108 and into the electrode 110, thereby creating a circuit. The voltage supply device 118 may comprise any reasonably suitable known device capable of supplying various levels of voltage through the conductive probe 104.

The electric potential applied through the conductive probe 104 is sufficient to cause the metal in the electrode 110, which is an anode in this case, to become metal ions. The metal ions become dissolved in the electrolyte layer 108. The volume of metal ions dissolved in the electrolyte layer 108 generally corresponds to the counter electrode, which in this case is the conductive element 126 contacted by the conductive probe 104. The metal ions dissolved in the electrolyte layer 108 form a conductive path such as configuring a metallic dendrite 120 by precipitation from the solid solution of cations on the conductive element 126, which is a cathode in this case. The growth of the dendrite 120 between the conductive element 126 and the electrode 110 decreases the resistance in the electrolyte layer 108 between the selected conductive element 126 and the electrode 110.

The conductive probe 104 may be moved to another desired conductive element 126 and the process described hereinabove may be repeated to write to the other desired conductive element 126. This process may be repeated any number of times to write data onto variously located memory cells 106′ defined by the conductive elements 126.

To perform a read operation, the conductive probe 104 is positioned over a desired conductive element 126. Again, the positioning of the conductive probe 104 over the desired conductive element 126 may be effectuated in manners as described hereinabove. Once the conductive probe 104 is positioned over and in contact with the desired conductive element 126, an electric potential is applied from the conductive probe 104, through the desired conductive element 126 and to the electrode 112. The level of voltage applied is selected to substantially prevent dendrite 120 formation in the electrolyte layer 108 at the location of the memory cell 106′. Thus, for instance, the voltage applied through the conductive probe 104 may be less than the voltage applied during a writing or erasing operation.

The level of resistance between the conductive element 126 and the electrode 110 through the electrolyte layer 108 depends on the presence of a conductive path such as a dendrite 120. For instance, the resistance is lower between the conductive element 126 and the electrode 110 when the dendrite 120 is present in the electrolyte layer 108 therebetween. Alternatively, the resistance between the conductive element 126 and the electrode 110 is higher if there is no dendrite 120 formation between the conductive element 126 and the electrode 110.

The resistance in the electrolyte layer 108 between the conductive element 126 and the electrode 110 may be detected by, for instance, a resistance measuring device 122. The resistance measuring device 122 may comprise any reasonably suitable conventional resistance measuring device capable of measuring the resistance between the conductive element 126 and the electrode 110. The level of resistance may be characterized as 1's and 0's and the storage device 100′ may comprise a binary memory storage system. Thus, for instance, each of the conductive elements 126 may constitute a bit or memory cell 106′ in the binary memory storage system.

In the storage device 102′, a higher resistance may be characterized as a 0 and a lower resistance may be characterized as a 1, although the alternate characterization may also be employed without deviating from the scope of the invention. Thus, the conductive probe 104 may be implemented to determine whether the selected conductive element 126 is characterized as a 1 or a 0. In addition, through relative movement between the conductive probe 104 and the storage medium 102′, the locations of the 1′s and 0′s may be determined through detection of the resistance at the various locations of the conductive elements 126.

To perform an erase operation, the conductive probe 104 is positioned over a desired conductive element 126. The positioning of the conductive probe 104 over the desired conductive element 126 may be performed as described hereinabove. Once the conductive probe 104 is positioned over and is in contact with the desired conductive element 126, an electric potential is established between the conductive probe 104 to the electrode 110, thereby creating a circuit. The potential applied through the conductive probe 104 has a reverse bias as compared with the electric potential applied during the writing operation described hereinabove. The reverse bias voltage generally causes the metal ions in the dendrite 120 to diffuse back to the electrode 110, to become metal again. In other words, the reverse bias voltage generally operates to reconfigure, or otherwise render less conductive, the dendrite 120 in the electrolyte layer 108. This operation causes the resistance between the selected conductive element 126 and the electrode 110 to return to its high resistance state.

The erase operation may be repeated any number of times on variously “written” ones of the conductive elements 126 to return those areas back to the high resistance state. In this regard, the conductive probe 104 may be maneuvered over the desired conductive elements 126 to perform the erase operations. In addition, the relative movement between the conductive probe 104 and the storage device 102′ may be implemented in any of the manners described hereinabove.

The storage device 100′ may include additional components not specifically illustrated in FIGS. 3 and 4. For instance, the storage device 100′ may include controllers designed to determine when and for which of the conductive elements 126, read, write, or erase operations are to be performed. The storage device 100′ may also include controllers for controlling the relative movements of the conductive probe 104 and the storage device 102′ as well as controllers for controlling the electric potential to be applied through the conductive probe 104. The means of relative motion between the conductive probe 104 and the storage medium 102′, for instance, a MEMS device, may also be included in the storage device 100′.

By virtue of certain embodiments of the invention, data may be stored in a substantially non-volatile storage device having a relatively high density, e.g., greater than 10 Gb/cm². In addition, the storage device may be configured and employed in a relatively simple and inexpensive manner as compared with certain known storage devices.

What has been described and illustrated herein is a preferred embodiment of the invention along with some of its variations. The terms, descriptions and figures used herein are set forth by way of illustration only and are not meant as limitations. Those skilled in the art will recognize that many variations are possible within the spirit and scope of the invention, which is intended to be defined by the following claims—and their equivalents—in which all terms are meant in their broadest reasonable sense unless otherwise indicated.

1. A data storage device comprising:
a storage medium comprising;
an electrode; and
an electrolyte layer positioned on the electrode;
at least one probe configured to contact the electrolyte layer, wherein the electrolyte layer is positioned between the probe and the electrode; and
a voltage supply device configured to supply voltage through the at least one probe and the electrode to thereby create a circuit between the at least one probe and the electrode, wherein the level of voltage supplied by the at least one probe allows at least one of writing, reading, and erasing operations on one or more memory cells of the storage medium.

2. The device according to claim 1, wherein the electrode comprises one or more of gold, silver, copper, platinum, iridium, and palladium.

3. The device according to claim 1, wherein the electrolyte layer comprises a chalcogenide-metal composition.

4. The device according to claim 3, wherein the chalcogenide-metal composition comprises one or more of arsenic, germanium, selenium, sulfur, oxygen, tellurium, and antimony.

5. The device according to claim 3, wherein the chalcogenide-metal composition comprises one or more of silver, gold, platinum, palladium, copper, and iridium.

6. The device according to claim 1, wherein one or both of the storage medium and the at least one probe are movable with respect to each other.

7. The device according to claim 1, further comprising:
a voltage supply device is configured to supply a first voltage to perform a write operation in one or more memory cells of the storage medium, said first voltage being sufficiently high to form a conductive path such as configuring a metallic dendrite in the electrolyte layer at the locations of the one or more memory cells.

8. The device according to claim 7, wherein the voltage supply device is configured to supply a second voltage to perform an erase operation in one or more memory cells of the storage medium, said second voltage having a reverse bias as compared to the first voltage, wherein the second voltage is operable to render a less conductive path in the electrolyte layer at the locations of the one or more memory cells.

9. The device according to claim 8, the voltage supply device is configured to supply a third voltage to perform a read operation on one or more memory cells of the storage medium, wherein the third voltage is a lower voltage than the first voltage or the second voltage and is sufficiently weak to cause little modification of the memory cell, said device further comprising:
a resistance measuring device configured to detect the resistance between the at least one probe and the electrode.

10. The device according to claim 1, wherein the at least one probe comprises an inverted conical tip configured to contact the electrolyte layer.

11. The device according to claim 1, wherein the storage medium further comprises:
a conductive layer positioned on the electrolyte layer, wherein the at least one probe is configured to contact the conductive layer.

12. The device according to claim 11, wherein the conductive layer contains a metal comprising at least one of platinum, palladium, gold, iridium, silver, copper, and other materials that do not comprise or form insulating oxides.

13. The device according to claim 11, wherein the conductive layer comprises a plurality of discrete conductive elements spaced apart from each other discontinuously, wherein the plurality of discrete conductive elements are associated with memory cells.

14. The device according to claim 13, wherein the electrode is sized and positioned to create an electric circuit with the plurality of discrete conductive elements.

15. The device according to claim 14, further comprising:
a voltage supply device configured to supply a first voltage to perform a write operation at the locations of the discrete conductive elements, said first voltage being sufficiently high to form a conductive path such as configuring a metallic dendrite in the electrolyte layer at the locations of the one or more memory cells associated with the discrete conductive elements.

16. The device according to claim 15, wherein the voltage supply device is configured to supply a second voltage to perform an erase operation at the locations of the discrete conductive elements, said second voltage having a reverse bias as compared to the first voltage, wherein the second voltage is operable to render less conductive in the electrolyte layer at the locations of the one or more memory cells associated with the discrete conductive elements.

17. The device according to claim 16, the voltage supply device is configured to supply a third voltage to perform a read operation at the locations of the discrete conductive elements, wherein the third voltage is a lower voltage than the first voltage or the second voltage and is sufficiently weak to cause little modification of the memory cell, said device further comprising:
a resistance measuring device configured to detect the resistance between the at least one probe and the electrode at the locations of the one or more memory cells associated with the discrete conductive elements, said resistance being lower in those memory cells.

18. A method for storing data in a storage medium having an electrode and an electrolyte layer positioned on the electrode, said method comprising:
contacting at least one probe on the electrolyte layer, wherein the at least one probe is separate from the storage medium;
applying a voltage through the at least one probe at one or more memory cell locations such that one or more circuits are formed between the at least one probe and the electrode, wherein application of the voltage allows at least one of a writing, reading, and erasing operation on the one or more memory cells of the storage medium.

19. The method according to claim 18, wherein the step of applying a voltage comprises applying a first voltage having sufficient strength to form a conductive path such as configuring a metallic dendrite in the electrolyte layer to perform a writing operation at the locations of the one or more memory cells.

20. The method according to claim 19, wherein the step of applying a voltage comprises applying a second voltage having a reverse bias of the first voltage, said second voltage having sufficient strength to render less conductive in the electrolyte layer to perform an erasing operating at the locations of the one or more memory cells.

21. The method according to claim 20, wherein the step of applying a voltage comprises applying a third voltage having a lower strength than the first voltage or the second voltage, said third voltage also being sufficiently weak to cause little modification of the memory cell, said method further comprising:
determining the resistance between the at least one probe and the electrode to perform a reading operation at the locations of the one or more memory cells.

22. The method according to claim 21, wherein the step of determining the resistance further comprises assigning values to both of a higher resistance and a lower resistance, wherein the lower resistance is detected in the presence of a metallic dendrite at the locations of the one or more memory cells.

23. The method according to claim 22, wherein the step of assigning values comprises consistently assigning a “1” to the memory cells having metallic dendrites in the electrolyte layer and consistently assigning a “0” to other memory cells.

24. The method according to claim 22, wherein the step of assigning values comprises consistently assigning a “0” to the memory cells having metallic dendrites in the electrolyte layer and consistently assigning a “1” to other memory cells.

25. The method according to claim 18, said method further comprising:
moving one or both of the at least one probe and the storage medium with respect to each other to position the at least one probe over various ones of the one or more memory cells.

26. The method according to claim 18, wherein a conductive layer formed of discrete conductive elements is positioned on the electrolyte layer, and wherein the step of applying a voltage comprises applying a first voltage having sufficient strength to form a conductive path such as configuring a metallic dendrite in the electrolyte layer at the locations of the discrete conductive elements to perform a writing operation at the locations of the one or more memory cells associated with the discrete conductive elements.

27. The method according to claim 26, wherein the step of applying a voltage comprises applying a second voltage having a reverse bias of the first voltage, said second voltage having sufficient strength to render less conductive in the electrolyte layer to perform an erasing operating at the locations of the one or more memory cells associated with the discrete conductive elements.

28. The method according to claim 27, wherein the step of applying a voltage comprises applying a third voltage having a lower strength than the first voltage or the second voltage, said third voltage also being sufficiently weak to cause little modification of the memory cell, said method further comprising:
determining the resistance between the at least one probe and the electrode at the locations of the one or more memory cells associated with the discrete conductive elements to perform a reading operation at the locations of the one or more memory cells.

29. The method according to claim 28, wherein the step of determining the resistance further comprises assigning values to both of a higher resistance and a lower resistance, wherein the lower resistance is detected in the presence of a conductive path such as a metallic dendrite at the locations of the one or more memory cells associated with the discrete conductive elements.

30. The method according to claim 28, wherein the step of assigning values comprises consistently assigning a “1” to the memory cells associated with the discrete conductive elements having metallic dendrites in the electrolyte layer and consistently assigning a “0” to other memory cells.

31. The method according to claim 28, wherein the step of assigning values comprises consistently assigning a “0” to the memory cells associated with the discrete conductive elements having metallic dendrites in the electrolyte layer and consistently assigning a “1” to other memory cells.

32. The method according to claim 26, said method further comprising:
moving one or both of the at least one probe and the storage medium with respect to each other to position the at least one probe over various ones of the discrete conductive elements.

33. A system for storing data in one or more memory cells of a storage device with at least one probe, said one or more memory cells having an electrode and an electrolyte layer positioned on the electrode, said system comprising:
means for enabling contact between the at least one probe and the electrolyte layer; and
means for applying a voltage through the at least one probe such that a circuit is formed between the at least one probe and the electrode, wherein application of the voltage allows at least one of writing, reading, and erasing operations on the one or more memory cells of the storage medium.

34. The system according to claim 33, wherein the means for applying a voltage comprises means for applying a first voltage having a sufficient strength to form a conductive path such as configuring a metallic dendrite in the electrolyte layer to perform a writing operation in one or more memory cells.

35. The system according to claim 34, wherein the means for applying a voltage comprises means for applying a second voltage having a reverse bias of the first voltage, said second voltage having sufficient strength to render less conductive in the electrolyte layer at the locations of the one or more memory cells to perform an erasing operation.

36. The system according to claim 35, wherein the means for applying a voltage comprises means for applying a third voltage having a lower strength than the first voltage or the second voltage, said third voltage also being sufficiently weak to cause little modification of the memory cell, said system further comprising:
means for determining the resistance between the at least one probe and the electrode to perform a reading operation on the one or more memory cells.

37. The system according to claim 36, wherein the means for determining the resistance comprises means for assigning values to both of a higher resistance and a lower resistance, wherein the lower resistance is detected in the presence of a conductive path such as a metallic dendrite at the locations of the one or more memory cells.

38. The system according to claim 37, wherein the means for assigning values is operable to consistently assign a “1” to the memory cells having conductive paths such as metallic dendrites in the electrolyte layer and to consistently assign a “0” to other memory cells.

39. The system according to claim 37, wherein the means for assigning values is operable to consistently assign a “0” to the memory cells having conductive paths such as metallic dendrites in the electrolyte layer and to consistently assign a “1” to other memory cells.

40. The system according to claim 33, said system further comprising:
means for moving one or both of the at least one probe and the storage medium with respect to each other to position the at least one probe over various ones of the one or more memory cells.

41. The system according to claim 33, wherein a conductive layer formed of discrete conductive elements is positioned on the electrolyte layer, and wherein the means for applying a voltage comprises means for applying a first voltage having a sufficient strength to form a conductive path such as configuring a metallic dendrite in the electrolyte layer at the locations of the discrete conductive elements to perform a writing operation in one or more memory cells associated with the discrete conductive elements.

42. The system according to claim 41, wherein the means for applying a voltage comprises means for applying a second voltage having a reverse bias of the first voltage, said second voltage having sufficient strength to render less conductive in the electrolyte layer at the locations of the one or more memory cells associated with the discrete conductive elements to perform an erasing operation.

43. The system according to claim 42, wherein the means for applying a voltage comprises means for applying a third voltage having a lower strength than the first voltage or the second voltage, said third voltage also being sufficiently weak to cause little modification of the memory cell, said system further comprising:
means for determining the resistance between the at least one probe and the electrode at the locations of the one or more memory cells associated with the discrete conductive elements to perform a reading operation on the one or more memory cells.

44. The system according to claim 43, wherein the means for determining the resistance comprises means for assigning values to both of a higher resistance and a lower resistance, wherein the lower resistance is detected in the presence of a conductive path such as a metallic dendrite at the locations of the one or more memory cells associated with the discrete conductive elements.

45. The system according to claim 44, wherein the means for assigning values is operable to consistently assign a “1” to the memory cells associated with the discrete conductive elements having conductive paths such as metallic dendrites in the electrolyte layer and to consistently assign a “0” to other memory cells.

46. The system according to claim 44, wherein the means for assigning values is operable to consistently assign a “0” to the memory cells associated with the discrete conductive elements having conductive paths such as metallic dendrites in the electrolyte layer and to consistently assign a “1” to other memory cells.

47. The system according to claim 33, said system further comprising:
means for moving one or both of the at least one probe and the storage medium with respect to each other to position the at least one probe over various ones of the discrete conductive elements.

48. A computer readable storage medium on which is embedded one or more computer programs, said one or more computer programs implementing a method for storing data in a storage medium having a an electrode and an electrolyte layer positioned on the electrode, said one or more computer programs comprising a set of instructions for:
contacting at least one probe on the electrolyte layer, wherein the at least one probe is separate from the storage medium;
applying a voltage through the at least one probe at the one or more memory cell locations such that one or more circuits are formed between the at least one probe and the electrode, wherein application of the voltage allows at least one of a writing, reading, and erasing operation on the one or more memory cells.

49. A computer readable storage medium on which is embedded one or more computer programs, said one or more computer programs implementing a method for storing data in a storage medium having a an electrode, a discontinuous conductive layer and an electrolyte layer positioned on the electrode, said one or more computer programs comprising a set of instructions for:
contacting at least one probe on the discontinuous conductive layer, wherein the at least one probe is separate from the storage medium;
applying a voltage through the at least one probe at the one or more memory cell locations such that one or more circuits are formed between the at least one probe and the electrode, wherein application of the voltage allows at least one of a writing, reading, and erasing operation on the one or more memory cells.
